(19) United States
(12) Patent Application Publication
(10) Pub. No.: US 2003/0132433 A1
(43) Pub. Date: Jul. 17, 2003

(54) Semiconductor structures including a gallium nitride material component and a silicon germanium component

(76) Inventors: Edwin L. Piner, Cary, NC (US); T. Warren Weeks, Raleigh, NC (US); Ricardo M. Borges, Morrisville, NC (US); Kevin J. Linthicum, Angier, NC (US)

Correspondence Address: WOLF GREENFIELD & SACKS, PC, FEDERAL RESERVE PLAZA, 600 ATLANTIC AVENUE, BOSTON, MA, 02210-2211, US

(21) Appl. No.: 10/047,455

(22) Filed: Jan. 15, 2002

(51) Int. Cl. H01L 29/06; H01L 31/0328; H01L 31/0336; H01L 31/072; H01L 31/109

(52) U.S. Cl. 257/19

(57) ABSTRACT

The invention provides semiconductor structures that include a gallium nitride material component and a silicon germanium component, as well as methods of forming such structures. The gallium nitride material component may be a layer formed on a substrate, or may be the substrate itself. Similarly, the silicon germanium component may be a layer formed on a substrate, or may be the substrate itself. Crack formation within the two components can be limited by matching the thermal expansion rates of the gallium nitride material and the silicon germanium and, thus, inhibiting the generation of thermal stresses within the components. The semiconductor structures may be used in a number of microelectronic and optoelectronic applications, amongst others.

### FIELD OF INVENTION

The invention relates generally to semiconductor structures and, more particularly, to semiconductor structures that include a gallium nitride material component and a silicon germanium component.

### BACKGROUND OF INVENTION

Gallium nitride materials include gallium nitride (GaN) and GaN alloys such as aluminum gallium nitride (AlGaN), indium gallium nitride (InGaN), and aluminum indium gallium nitride (AlInGaN). These materials are semiconductor compounds that have a relatively wide, direct bandgap which permits highly energetic electronic transitions to occur. Such electronic transitions impart gallium nitride materials with a number of attractive properties including the ability to efficiently emit blue light and the ability to transmit signals at high frequency, amongst others. Accordingly, gallium nitride materials are being widely investigated in many microelectronic and optoelectronic applications.

In many applications, gallium nitride materials are grown on substrates. However, property differences between gallium nitride materials and substrate materials can sacrifice the quality of the resulting gallium nitride material layer. For example, gallium nitride (GaN) has a different thermal expansion coefficient than many substrate materials including sapphire, silicon carbide, and silicon (GaN has a thermal expansion coefficient (x 10⁻⁶/K) for the a₀ lattice parameter of about 5.59 and Si has a thermal expansion coefficient (x 10⁻⁶/K) for the aₒ lattice parameter of about 4.2). The different thermal expansion coefficients can generate stresses within a gallium nitride layer deposited on such substrates. The stresses can arise, for example, when the structure is cooled after the deposition of the gallium nitride layer and the substrate contracts at a different rate than the gallium nitride material layer. Such stresses can form cracks within the gallium nitride layer. This cracking phenomena can prevent gallium nitride materials from being suitable for use in many applications. Cracking can be particularly problematic for relatively thick (e.g., >0.5 micron) gallium nitride layers.

### SUMMARY OF INVENTION

The invention provides semiconductor structures that include a gallium nitride material component and a silicon germanium component, as well as methods of forming such structures.

In one aspect, the invention provides a semiconductor structure. The structure includes a silicon germanium component and a gallium nitride material component.

In another aspect, the invention provides a semiconductor structure. The structure includes a silicon germanium component, and a gallium nitride material layer formed on the silicon germanium component. The gallium nitride material layer has a crack level of less than 0.005 μm/μm².

In another aspect, the invention provides a semiconductor structure. The structure includes a silicon substrate and a silicon germanium layer formed on the silicon substrate. The structure further includes a gallium nitride material layer formed on the silicon germanium layer.

In another aspect, the invention provides a semiconductor structure. The structure includes a substrate, a silicon germanium component formed on the substrate, and a gallium nitride material component formed on the substrate. The structure forms a first semiconductor device that includes the silicon germanium component and a second semiconductor device that includes the gallium nitride material component. The first semiconductor device is integrated with the second semiconductor device.

In another aspect, the invention provides a method of forming a semiconductor structure. The method includes forming a gallium nitride material layer on a silicon germanium component.

In another aspect, the invention provides a method of forming a semiconductor structure. The method includes forming a silicon germanium layer on a gallium nitride component.

Other aspects, embodiments and features of the invention will become apparent from the following detailed description of the invention when considered in conjunction with the accompanying drawings. All patent applications and patents incorporated herein by reference are incorporated by reference in their entirety. In case of conflict, the present specification, including definitions, will control.

### BRIEF DESCRIPTION OF THE DRAWINGS

FIG. 1 illustrates a semiconductor material including a silicon germanium layer formed between a substrate and a gallium nitride material layer according to one embodiment of the present invention.

FIG. 2 illustrates a semiconductor material including a gallium nitride material layer formed on a silicon germanium substrate according to another embodiment of the present invention.

FIG. 3 illustrates a semiconductor material including an intermediate layer formed between a silicon germanium layer and a gallium nitride material layer according to another embodiment of the present invention.

FIG. 4 illustrates a semiconductor device according to another embodiment of the present invention.

FIG. 5 illustrates a FET according to another embodiment of the present invention.

FIG. 6 illustrates a MODFET according to another embodiment of the present invention.

FIG. 7 illustrates an LED according to another embodiment of the present invention.

FIG. 8 illustrates a laser diode according to another embodiment of the present invention.

FIGS. 9 and 10 respectively illustrate semiconductor structures that include a gallium nitride material-based device integrated with the silicon germanium-based device according to other embodiments of the present invention.

### DETAILED DESCRIPTION

The invention provides semiconductor structures that include a gallium nitride material component and a silicon germanium component, as well as methods of forming such structures. The gallium nitride material component may be a layer formed on a substrate, or may be the substrate itself. Similarly, the silicon germanium component may be a layer formed on a substrate, or may be the substrate itself. As described further below, crack formation within the two components can be limited by matching the thermal expansion coefficients of the gallium nitride material and the silicon germanium and, thus, inhibiting the generation of thermal stresses within the components. The semiconductor structures may be used in a number of microelectronic and optoelectronic applications, amongst others.

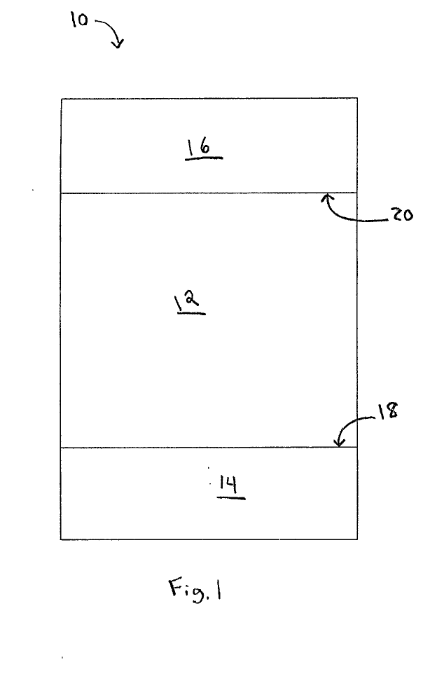

FIG. 1 shows a semiconductor material 10 according to one embodiment of the present invention. Semiconductor material 10 includes a silicon germanium layer 12 formed on a substrate 14 and a gallium nitride material layer 16 formed on the silicon germanium layer.

It should be understood that when a layer is referred to as being “on” or “over” another layer or substrate, it can be directly on the layer or substrate, or an intervening layer also may be present. A layer that is “in direct contact with” another layer or substrate means that no intervening layer is present. It should also be understood that when a layer is referred to as being “on” or “over” another layer or substrate, it may cover the entire layer or substrate, or only a portion of the layer or substrate.

Silicon germanium layer 12 may be formed of any SiₓGe₍₁₋ₓ₎ alloy, wherein 0<x<1. The composition of the silicon germanium layer may be selected to provide the layer with a desired thermal expansion coefficient. The thermal expansion coefficient of the SiₓGe₍₁₋ₓ₎ alloy depends, at least in part, on the relative concentration of silicon and germanium within layer 12. Silicon has a thermal expansion coefficient of about 4.2 (x 10⁻⁶/K) and germanium has a thermal expansion coefficient of about 6.1 (x 10⁻⁶/K). Thus, increasing the germanium concentration and decreasing the silicon concentration (decreasing x) of the alloy increases its thermal expansion coefficient.

In some embodiments, the composition of silicon germanium layer 12 may be controlled to result in a thermal expansion coefficient similar to that of gallium nitride material layer 16. Similar thermal expansion rates cause silicon germanium layer 12 and gallium nitride material layer 16 to contract at similar rates when they are cooled from deposition temperatures (e.g., between about 1000° C. and about 1200° C.). Such a condition has been found particularly effective in minimizing the generation of cracks within the gallium nitride material layer, as well as, the silicon germanium layer.

It should be understood that the thermal expansion coefficients for the silicon germanium layer and the gallium nitride material layer are not required to be equal. In some cases, the thermal expansion coefficient of the silicon germanium layer is within ±25%, or ±10%, of the thermal expansion coefficient of the gallium nitride material. In other cases, the thermal expansion coefficient of the silicon germanium layer is substantially equal (e.g., within ±1%) to the thermal expansion coefficient of the gallium nitride material. The percentage difference between the thermal expansion coefficient of the silicon germanium layer and the gallium nitride material layer may depend upon the requirements of the application.

In some embodiments of the invention, the composition of the silicon germanium layer 12 may be selected to provide layer 12 with a dissimilar thermal expansion coefficient to that of gallium nitride material layer 16. The dissimilar expansion rates can generate stresses within the gallium nitride material layer upon cooling. For example, when the gallium nitride material layer has a larger thermal expansion coefficient than that of the silicon germanium layer, a tensile stress is generated within the gallium nitride material layer; and, when the gallium nitride material layer has a smaller thermal expansion coefficient than that of the silicon germanium layer, a compressive stress is generated within the gallium nitride material layer. In some cases, such as to enhance the piezo-electric effect or to controllably remove the substrate, it may be advantageous to generate such tensile stresses in the gallium nitride material layer. However, even in these cases, it may be important to limit the amount of tensile stress generated so as to restrict crack generation within the gallium nitride material layer.

In some embodiments, silicon germanium layer 12 has a silicon rich composition. Silicon rich compositions are oftentimes suitable to impart silicon germanium layer 12 with a similar thermal expansion coefficient as that of the gallium nitride material layer. In certain silicon rich compositions, the value of x in SiₓGe₍₁₋ₓ₎ is greater than or equal to 0.7; in other compositions, the value of x is greater than or equal to 0.8; and, in other compositions, the value of x is greater than or equal to 0.9.

Temperatures at which semiconductor material 10 are processed, in some cases, can limit the germanium content in layer 12. Layer 12 should not be subjected to temperatures that are above its melting point. Increasing the germanium content in the layer 12 decreases the melting point of layer 12. Therefore, the germanium content should be limited to an amount that ensures that the melting point of SiₓGe₍₁₋ₓ₎ layer 12 is greater than temperatures to which the layer is subjected. For example, as described above, the deposition temperature of gallium nitride material layer 16 is typically between about 1000° C. and 1200° C. To ensure that SiₓGe₍₁₋ₓ₎ layer 12 has a melting temperature of greater than 1000° C., the value of x should not be less than about 0.2.

In some cases, the composition of silicon germanium layer 12 is varied (or graded) across at least a portion of the thickness (t) of the layer. Such compositionally-graded layers can be particularly effective in providing sufficient stress relief to limit or prevent the formation of cracks in gallium nitride material layer 16. For example, the composition of the silicon germanium layer may be varied from a first composition at a back surface 18 of the layer to a second composition at a front surface 20 of the layer. In some cases, the composition at back surface 18 has a thermal expansion similar to that of the substrate and the composition at front surface 20 has a thermal expansion similar to that of gallium nitride material layer.

The composition of the silicon germanium layer 12 is varied by changing the silicon and the germanium concentration across the layer. In some cases, the germanium concentration is increased (i.e., the value of x decreases) in a direction away from substrate 14. For example, the concentration of germanium may be increased from a value of zero at back surface 18 to a positive value (e.g., about 0.2, about 0.3, etc.) at front surface 20. Utilizing a silicon germanium layer 12 that has a zero germanium concentration (x=1) at back surface 18 may be particularly preferred when a silicon substrate is used.

The composition of silicon germanium layer 12 may be varied in a number of different manners. For example, the composition may be graded continuously, discontinuously, linearly, non-linearly, across the entire thickness, or across only a portion of the thickness. Though certain embodiments may include a silicon germanium layer having a graded composition, it should be understood that other embodiments may utilize silicon germanium layers having a constant composition that is not varied across its thickness.

In some embodiments, the silicon germanium layer may be doped, for example, to effect electrical properties. Suitable dopants include carbon, amongst others.

The silicon germanium layer may be of any suitable thickness. Generally, the thickness is between about 0.01 microns and about 10 microns, though other thicknesses are possible.

Silicon germanium layer 12 may be an epitaxial layer having a monocrystalline structure. The crystalline structure may have a (111), (100), or (110) orientation, among others.

In the illustrative embodiment of FIG. 1, gallium nitride material layer 16 is formed on silicon germanium layer 12. As used herein, the term “gallium nitride material” refers to gallium nitride (GaN) and any of its alloys, such as aluminum gallium nitride (AlₓGa₍₁₋ₓ₎N), indium gallium nitride (In_{y}Ga_{(1-y)}N), aluminum indium gallium nitride (AlₓIn_{y}Ga_{(1-x-y)}N), gallium arsenide phosporide nitride (GaAsₐP_{b}N_{(1-a-b)}), aluminum indium gallium arsenide phosporide nitride (AlₓIn_{y}Ga_{(1-x-y)}AsₐP_{b}N_{(1-a-b)}), amongst others. Typically, when present, arsenic and/or phosphorous are at low concentrations (i.e., less than 5 weight percent).

The composition of the gallium nitride layer generally is primarily dictated by the application of semiconductor material 10. In some cases, the composition of the gallium nitride material layer may also be controlled, at least to some extent, so as to provide a similar thermal expansion coefficient to that of the silicon germanium layer. For example, the thermal expansion coefficient of AlₓGa₍₁₋ₓ₎N layer 16 can be increased by increasing the gallium concentration in the layer. However, it should be understood that generally there is more flexibility in varying the composition of the silicon germanium layer, as described above, to match the thermal expansion coefficient of the gallium nitride material layer.

In certain embodiments, gallium nitride material layer 16 has a high concentration of gallium and includes little or no amounts of aluminum and/or indium. In high gallium concentration embodiments, the sum of (x+y) may be less than 0.4, less than 0.2, less than 0.1, or even less. In some cases, it is preferable for the gallium nitride material layer to have a composition of GaN (i.e., x+y=0). In some cases, gallium nitride material layer 16 has a composition of AlₓGa₍₁₋ₓ₎N and, thus, includes aluminum but no indium. Gallium nitride materials may be doped n-type or p-type, or may be intrinsic. Suitable gallium nitride materials for layer 16 have also been described in commonly-owned U.S. patent application Ser. No. 09/736,972, filed Dec. 14, 2000, which is incorporated herein by reference.

As described above, gallium nitride material layer 16 has a low crack level as a result of the ability of silicon germanium layer 12 to relieve stress arising from differences in thermal expansion rates between substrate 14 and gallium nitride material layer 16. A “crack,” as used herein, is a linear fracture or a cleavage having a length to width ratio of greater than 5:1 that extends to the surface of the gallium nitride material. It should be understood that a crack may or may not extend through the entire thickness of the gallium nitride material layer. The term “crack level” is defined as a total measure of all crack lengths in a gallium nitride material per unit surface area. Crack level can be expressed in units of μm/μm².

The crack level of a gallium nitride material can be measured, for example, using optical microscopy techniques. To determine the crack level, the length of all of the cracks in a given area (i.e., 1 mm×1 mm) are added together and divided by the total surface area. If necessary, this process may be repeated at a number of locations across the surface to provide a measurement representative of the entire gallium nitride material. The crack level at each location may be averaged to provide a crack level for the material. The number of locations at which measurements are taken depends, in part, upon the amount of surface area of the gallium nitride material. When measuring the crack level of a gallium nitride material layer, measurements are not made within a region proximate to edges of the material known as an edge exclusion. The nominal edge exclusion is 5 mm from the edge. Edge effects in such regions may lead to increased crack levels and such regions are typically not used in device formation.

Gallium nitride material layer 16 advantageously has a low crack level. In some cases, gallium nitride material layer 16 has a crack level of less than 0.005 μm/μm². In some cases, gallium nitride material has a very low crack level of less than 0.001 μm/μm². In certain cases, it may be preferable for gallium nitride material layer 16 to be substantially crack-free as defined by a crack level of less than 0.0001 μm/μm².

Gallium nitride material layer 16 also may have a low defect level. For example, in some embodiments, gallium nitride material layer has a defect level of about 10⁹ defects/cm², or less. Defect levels may be determined using transmission electron microscopy (TEM) or other techniques known in the art.

In certain cases, gallium nitride material layer 16 has a monocrystalline structure. In some cases, gallium nitride material layer 16 has a Wurtzite (hexagonal) structure.

Substrate 14 may be any type known in the art including silicon, silicon carbide, sapphire, gallium nitride, and silicon germanium, amongst others. In certain embodiments, it may be preferable to use a silicon substrate. A silicon substrate, as used herein, refers to any substrate that includes a silicon layer. Examples of suitable silicon substrates include substrates that are composed of bulk silicon (e.g., silicon wafers), silicon-on-insulator (SOI) substrates, silicon-on-sapphire substrates (SOS), silicon-on-diamond, silicon-on-AlN, silicon-on-(poly)SiC and separation by implanted oxygen (SIMOX) substrates, amongst others. Silicon substrates having different crystallographic orientations may be used. In some cases, silicon (111) substrates are preferred. In other cases, silicon (100) substrates are preferred. In other embodiments, it may be preferable to use a silicon germanium substrate. Silicon germanium substrates may be used, in particular, in connection with silicon germanium layers 12 having a graded composition.

Substrate 14 may have any dimensions used in the art and its particular dimensions are dictated by the application. Suitable diameters include, but are not limited to, 2 inches (50 mm), 4 inches (100 mm), 6 inches (150 mm), and 8 inches (200 mm). The dimensions of the substrate are also dictated, at least to some extent, on its type.

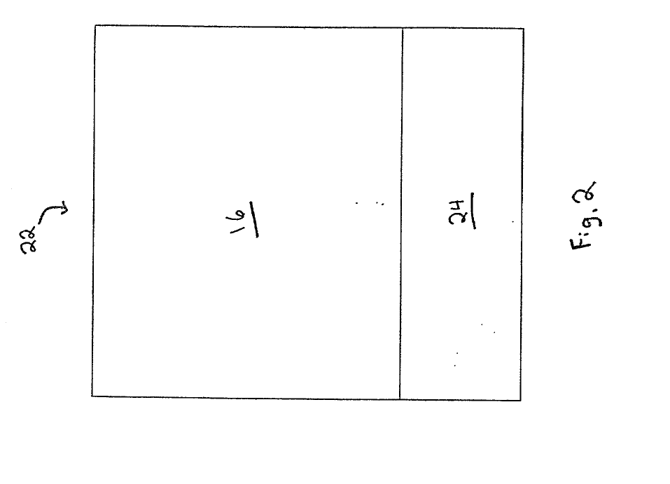

FIG. 2 illustrates a semiconductor material 22 including gallium nitride material layer 16 formed on a silicon germanium substrate 24 according to another embodiment of the present invention. In this embodiment, the advantages of limiting crack generation within the gallium nitride material layer are accomplished by forming gallium nitride material layer 16 directly on the silicon germanium substrate in the absence of a separate silicon germanium layer (12, FIG. 1). Thus, silicon germanium substrate 24 performs the function of the silicon germanium layer (12, FIG. 1).

Silicon germanium substrate 24 may have any of the compositions described above in connection with silicon germanium layer (12, FIG. 1). For example, silicon germanium substrate 24 may be formed of any SiₓGe₍₁₋ₓ₎ alloy, wherein 0<x<1. Also, in some embodiments, the composition of silicon germanium substrate 24 is selected to have a similar thermal expansion coefficient to that of gallium nitride material layer 16, as described above.

It should also be understood that, in another embodiment, the invention provides a semiconductor material that includes a silicon germanium layer formed upon a gallium nitride material substrate and that the respective compositions are selected to have similar thermal expansion coefficients, as described above.

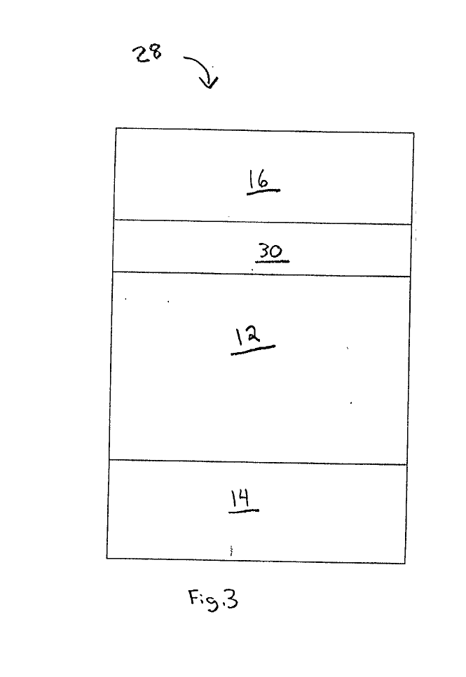

FIG. 3 illustrates a semiconductor material 28 including an intermediate layer 30 formed between silicon germanium layer 12 and gallium nitride material layer 16 according to another embodiment of the present invention. Intermediate layer 30 may be provided for any number of reasons including providing additional stress relief with gallium nitride material layer 16, providing thermal dissipation, providing electrical insulation for transistors, or providing electrical conduction for vertically conducting devices such as LEDs and laser diodes.

In some cases, intermediate layer 30 is formed of a gallium nitride material. Such gallium nitride material intermediate layers may be compositionally-graded to provide additional stress relief within gallium nitride material layer. Suitable compositionally graded gallium nitride material layers have been described in U.S. patent application Ser. No. 09/736,972, referenced above and incorporated herein by reference. In other cases, intermediate layer 30 may be formed of a constant composition.

It should be understood that though semiconductor material 28 includes one intermediate layer, semiconductor materials of the invention may include more than one intermediate layer. Furthermore, intermediate layer(s) may be formed at other locations within the semiconductor material, such as between the substrate and the silicon germanium layer.

The semiconductor materials of the invention may be processed using conventional techniques. For example, gallium nitride material layer 16, silicon germanium layer 12, and intermediate layer(s) 30 may be formed using metalorganic chemical vapor deposition (MOCVD), molecular beam epitaxy (MBE), and hydride vapor phase epitaxy (HVPE), amongst other techniques. In some cases, an MOCVD process may be preferred to form one or more of the layers. A suitable MOCVD process to form a gallium nitride material layer and a compositionally-graded intermediate layer has been described in U.S. patent application Ser. No. 09/736,972, which is incorporated herein by reference as described above. In some cases, a single MOCVD step may be used to form multiple layers. When using the single deposition step, the processing parameters are suitably changed at the appropriate time to form the different layers.

In some cases, gallium nitride material layer 16 is grown using a lateral epitaxial overgrowth (LEO) technique that involves growing an underlying gallium nitride layer through mask openings and then laterally over the mask to form the gallium nitride material device region, for example, as described in U.S. Pat. No. 6,051,849. In some cases, gallium nitride material layer 16 is grown using a pendeoepitaxial technique that involves growing sidewalls of gallium nitride material posts into trenches until growth from adjacent sidewalls coalesces to form a gallium nitride material layer, for example, as described in U.S. Pat. No. 6,177,688.

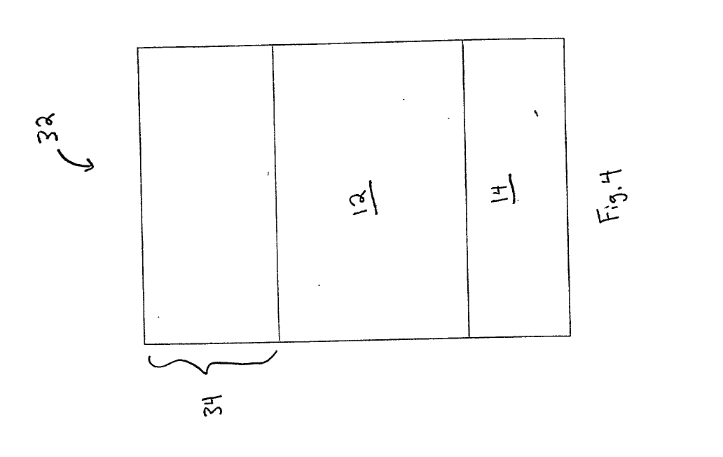

The semiconductor materials of the invention are typically processed to form semiconductor devices. FIG. 4 schematically shows a semiconductor device 32 according to one embodiment of the invention. Semiconductor device 32 includes a gallium nitride material device region 34 formed on silicon germanium layer 12. It should also be understood that device region 34 may also be formed in embodiments that include a silicon germanium substrate (24, FIG. 2) instead of a silicon germanium layer, and embodiments that include one or more intermediate layers (30, FIG. 3). In some cases, the active regions of the semiconductor device may be formed entirely within device region 34. In other cases, however, active regions may be formed only in part within gallium nitride material device region 34 and may also be formed in other regions of the semiconductor device such as substrate 14.

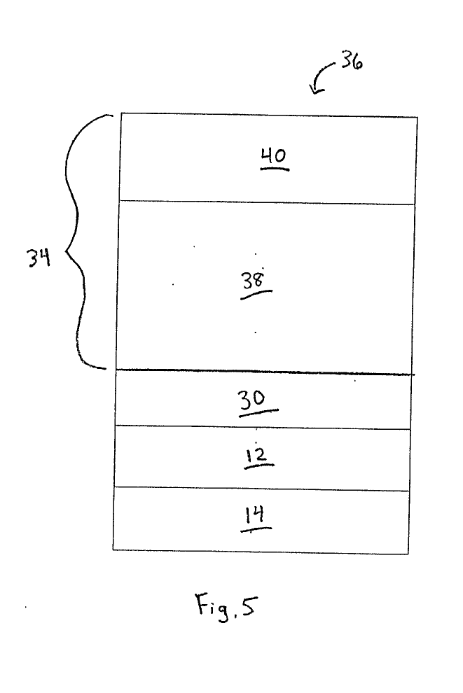

Device region 34 includes at least one gallium nitride material layer (16, FIG. 1). In some cases, device region 34 includes only one gallium nitride material layer. In other cases, as described further below and shown in FIGS. 5-8, gallium nitride material device region 34 includes more than one gallium nitride material layer. When present, the different gallium nitride material layers, for example, may have different compositions or may be doped differently. Device region 34 also may include one or more layers that do not have a gallium nitride material composition such as oxide layers or metallic layers.

The thickness of device region 34 and the number of different layers are dictated, at least in part, by the requirements of the specific application. At a minimum, the thickness of gallium nitride material device region 34 should be sufficient to permit formation of the desired device. Gallium nitride material device region 34 generally has a thickness of greater than 0.1 micron, though not always. In other cases, gallium nitride material device region 34 has a thickness of greater than 0.5 micron, greater than 0.75 micron, greater than 1.0 microns, greater than 2.0 microns, or even greater than 5.0 microns. Using the techniques described herein to limit crack generation, forming device region 34 having few or no cracks is possible even at the large thicknesses.

Any suitable semiconductor device known in the art including electronic and optical devices may be formed in connection with the invention. Exemplary devices include laser diodes (LDs), light emitting diodes (LEDs), power rectifier diodes, FETs (e.g., HFETs, MODFETs, MESFETs, MISFETs, and the like), bipolar junction transistors (BJTs), HBTs, NDRs, SAW devices, MEMS device, and UV detectors, amongst others. FIGS. 5-8 illustrate examples of gallium nitride material devices according to the invention. The illustrated examples show arrangements of layers within each device, but may not include every component of such devices including electrical contacts and the like. It should also be understood that devices having other structures are also within the scope of the invention.

FIG. 5 illustrates a heterojunction FET (HFET) 36 according to one embodiment of the present invention. HFET 36 includes a gallium nitride material device region 34 formed on intermediate layer 30. The intermediate layer is formed on silicon germanium layer 12 which, in turn, is formed on substrate 14. In the illustrative embodiment, the following layers comprise gallium nitride material device region 34 in succession: an intrinsic GaN layer 38 and an intrinsic AlGaN region 40 (e.g., containing between 10% to 40% by weight Al). In some embodiments, though not shown, HFET 36 includes a GaN layer (i.e., GaN cap) on top of intrinsic AlGaN region 40. It should be understood that HFETs having a variety of different structures may also be provided including HFETs formed on silicon germanium substrates that do not include a silicon germanium layer 12.

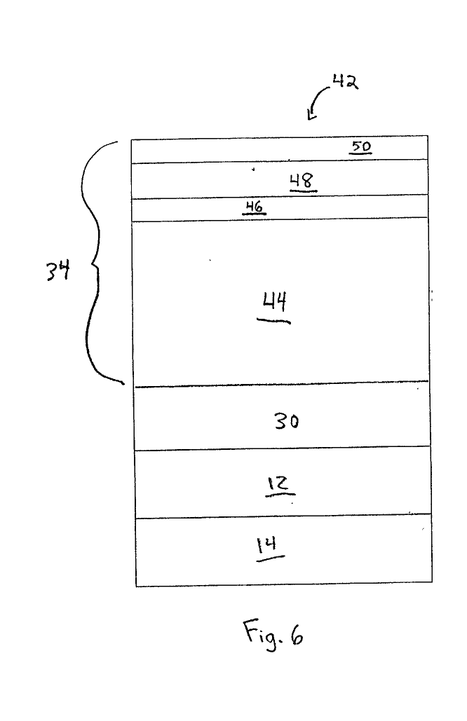

FIG. 6 illustrates a MODFET 42 according to another embodiment of the present invention. MODFET 42 includes a gallium nitride material device region 34 formed on intermediate layer 30. The intermediate layer is formed on silicon germanium layer 12 which, in turn, is formed on substrate 14. In the illustrative embodiment, the following layers comprise gallium nitride material device region 34 in succession: an intrinsic GaN layer 44, an intrinsic AlGaN region 46 (e.g., containing between 10% to 40% by weight Al), a silicon-doped AlGaN region 48 (e.g., containing between 10% to 40% by weight Al), and an intrinsic AlGaN region 50 (e.g., containing between 10% to 40% by weight Al). In some embodiments, though not shown, MODFET 36 includes a GaN layer (i.e., GaN cap) on top of intrinsic AlGaN region 50. It should be understood that MODFETs having a variety of different structures may also be provided including MODFETs formed on silicon germanium substrates that do not include a silicon germanium layer 12.

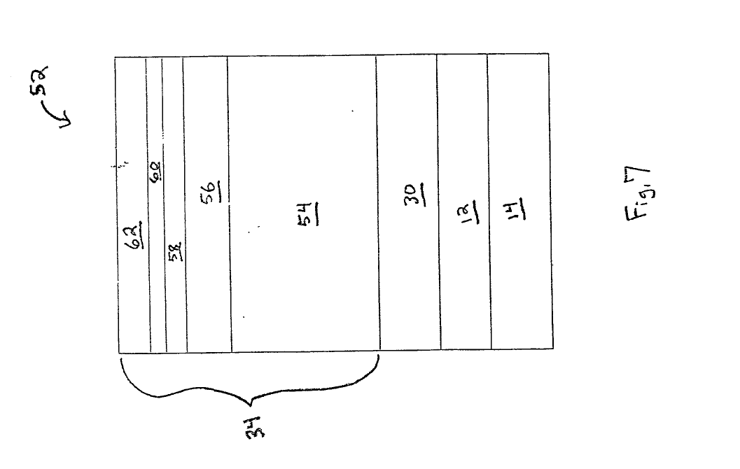

FIG. 7 illustrates an LED 52 according to another embodiment of the present invention. LED 52 includes a gallium nitride material device region 34 formed on intermediate layer 30. The intermediate layer is formed on silicon germanium layer 12 which, in turn, is formed on substrate 14. In the illustrative embodiment, the following layers comprise gallium nitride material device region 34 in succession: a silicon-doped GaN layer 54, a silicon-doped AlₓGa₍₁₋ₓ₎N layer 56 (e.g., containing 0-20% by weight Al), a GaN/InGaN single or multiple quantum well 58, a magnesium-doped AlₓGa₍₁₋ₓ₎N layer 60 (e.g., containing 10-20% by weight Al), and a magnesium-doped GaN layer 62. LED 52 may be provided as a variety of different structures including: a double heterostructure (Al>0% in layer 56), a single heterostructure (Al=0% in layer 56), a symmetric structure, or an asymmetric structure. It should be understood that LEDs having a variety of different structures may also be provided including LEDs formed on silicon germanium substrates that do not include a silicon germanium layer 12.

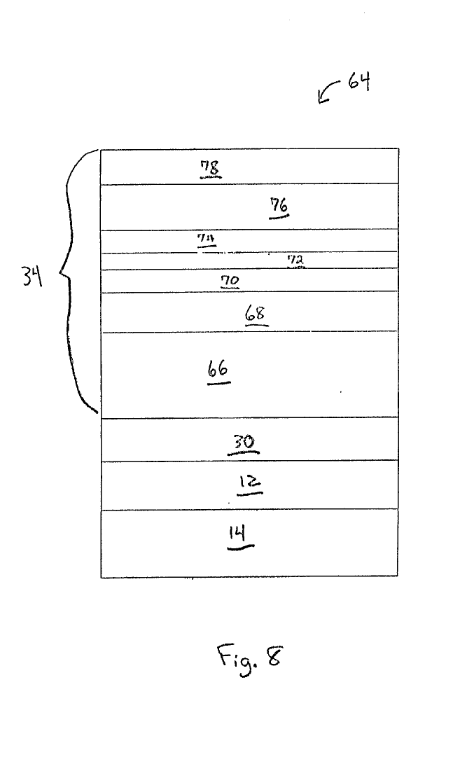

FIG. 8 illustrates a laser diode 64 according to another embodiment of the present invention. Laser diode 64 includes a gallium nitride material device region 34 formed on intermediate layer 30. The intermediate layer is formed on silicon germanium layer 12 which, in turn, is formed on substrate 14. In the illustrative embodiment, the following layers comprise gallium nitride material device region 34 in succession: a silicon-doped GaN layer 66, a silicon-doped AlₓGa₍₁₋ₓ₎N layer 68 (e.g., containing 10-20% by weight Al), a silicon-doped AlₓGa₍₁₋ₓ₎N layer 70 (e.g., containing 5-10% by weight Al), a GaN/InGaN single or multiple quantum well 72, a magnesium-doped AlₓGa₍₁₋ₓ₎N layer 74 (e.g., containing 5-10% by weight Al), a magnesium-doped AlₓGa₍₁₋ₓ₎N layer 76 (e.g., containing 10-20% by weight Al), and a magnesium-doped GaN layer 78. It should be understood that laser diodes having a variety of different structures may also be provided including laser diodes formed on silicon germanium substrates that do not include a silicon germanium layer 12.

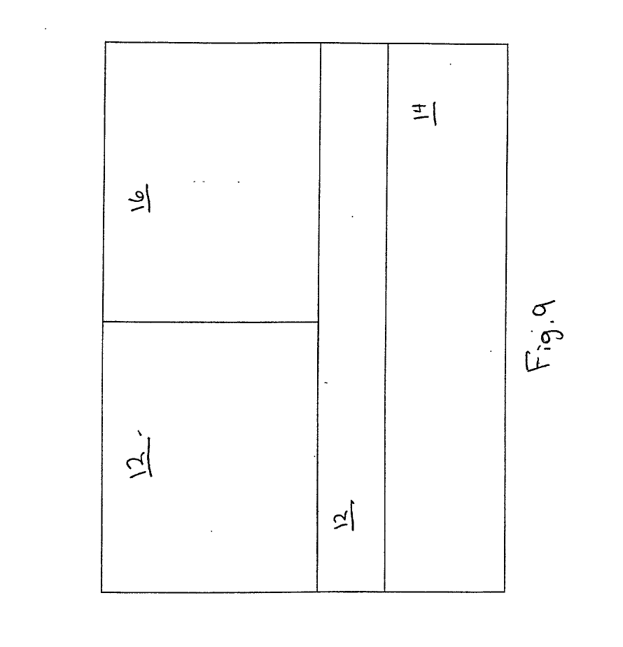

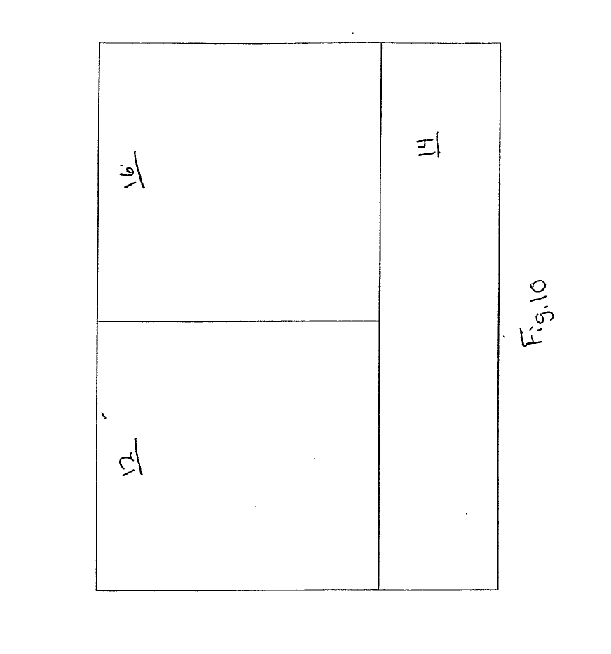

In other embodiments of the present invention, a first semiconductor device is formed which includes the gallium nitride material component and a second semiconductor device is formed which includes the silicon germanium component. The gallium nitride material-based device (e.g., FETs, LEDs or LDs) may be integrated with the silicon germanium-based device (e.g., SiGe-HBTs and SiGe/Si-MODFETs). For example, integrated silicon germanium-based devices may perform digital operations or be used as driver circuits for the gallium nitride material-based devices. In other cases, silicon germanium-based devices may perform high-frequency, relatively lower power functions in combination with a high-frequency, high-power GaN-based device. In embodiments that include integrated devices, it may be advantageous to form gallium nitride material layer 16 and silicon germanium layer 12 over different portions of substrate 14 (e.g., a silicon substrate), as shown in FIGS. 9 and 10. Layers 12 and 16 may be formed directly on substrate 14 (FIG. 9); or, on a SiₓGe₍₁₋ₓ₎ layer 16 (FIG. 10). It should be understood that other structures that include integrated devices are also contemplated.

Those skilled in the art would readily appreciate that all parameters listed herein are meant to be exemplary and that the actual parameters would depend upon the specific application for which the semiconductor materials and methods of the invention are used. It is, therefore, to be understood that the foregoing embodiments are presented by way of example only and that, within the scope of the appended claims and equivalents thereto the invention may be practiced otherwise than as specifically described.

What is claimed is:

1. A semiconductor structure comprising:
a silicon germanium component; and
a gallium nitride material component.

2. The semiconductor structure of claim 1, wherein the silicon germanium component is a layer.

3. The semiconductor structure of claim 2, wherein the silicon germanium layer is formed on a substrate.

4. The semiconductor structure of claim 3, wherein the silicon germanium layer is formed on a silicon substrate.

5. The semiconductor structure of claim 2, wherein the silicon germanium layer is formed on a silicon germanium substrate.

6. The semiconductor structure of claim 1, wherein the silicon germanium component is a substrate and the gallium nitride component is a layer formed on the silicon germanium substrate.

7. The semiconductor structure of claim 1, wherein the gallium nitride component is a layer.

8. The semiconductor structure of claim 7, wherein the gallium nitride layer is formed on a silicon substrate.

9. The semiconductor structure of claim 1, wherein the gallium nitride component is a substrate and the silicon germanium component is a layer formed on the gallium nitride substrate.

10. The semiconductor structure of claim 1, wherein the gallium nitride material component is in direct contact with the silicon germanium component.

11. The semiconductor structure of claim 1, further comprising an intermediate layer formed between the silicon germanium component and the gallium nitride material component.

12. The semiconductor structure of claim 11, wherein the intermediate layer is compositionally graded.

13. The semiconductor structure of claim 2, wherein the composition of the silicon germanium layer is graded.

14. The semiconductor structure of claim 13, wherein the germanium concentration of the silicon germanium layer is increased in a direction away from the substrate.

15. The semiconductor structure of claim 1, wherein the silicon germanium component has a monocrystalline structure.

16. The semiconductor structure of claim 1, wherein the silicon germanium component has a thermal expansion coefficient within ±25% of the thermal expansion coefficient of the gallium nitride material layer.

17. The semiconductor structure of claim 1, wherein the silicon germanium component comprises a SiₓGe₍₁₋ₓ₎ alloy and x is greater than or equal to 0.7.

18. The semiconductor structure of claim 17, wherein the silicon germanium component comprises a SiₓGe₍₁₋ₓ₎ alloy and x is greater than or equal to 0.8.

19. The semiconductor structure of claim 1, wherein the gallium nitride material component comprises a AlₓIn_{y}Ga_{(1-x-y)}N alloy.

20. The semiconductor structure of claim 19, wherein the sum of (x+y) is less than 0.2.

21. The semiconductor structure of claim 1, wherein the gallium nitride material component comprises GaN.

22. The semiconductor structure of claim 1, wherein the gallium nitride material component has a crack level of less than 0.005 μm/μm².

23. The semiconductor structure of claim 1, wherein the gallium nitride material layer forms at least a portion of a device region.

24. The semiconductor structure of claim 1, wherein the structure forms an FET.

25. The semiconductor structure of claim 1, wherein the structure forms an LED.

26. The semiconductor structure of claim 1, wherein the structure forms a laser diode.

27. The semiconductor structure of claim 1, wherein the structure forms a first semiconductor device that includes the silicon germanium component and a second semiconductor device that includes the gallium nitride material component.

28. The semiconductor structure of claim 27, wherein the first semiconductor device is integrated with the second semiconductor device.

29. A semiconductor structure comprising:
a silicon germanium component; and
a gallium nitride material layer formed on the silicon germanium component, the gallium nitride material layer having a crack level of less than 0.005 μm/μm².

30. A semiconductor structure comprising:
a silicon substrate;
a silicon germanium layer formed on the silicon substrate; and
a gallium nitride material layer formed on the silicon germanium layer.

31. A semiconductor structure comprising:
a substrate;
a silicon germanium component formed on the substrate; and
a gallium nitride material component formed on the substrate,
wherein the structure forms a first semiconductor device that includes the silicon germanium component and a second semiconductor device that includes the gallium nitride material component, the first semiconductor device being integrated with the second semiconductor device.

32. The semiconductor structure of claim 31, wherein the silicon germanium component and the gallium nitride component are formed on different portions of the substrate.

33. A method of forming a semiconductor structure comprising:
forming a gallium nitride material layer on a silicon germanium component.

34. The method of claim 33, wherein the silicon germanium component is a substrate.

35. The method of claim 33, wherein the silicon germanium component is a layer and further comprising forming the silicon germanium layer on a substrate.

36. The method of claim 33, wherein comprising forming the silicon germanium layer on a silicon substrate.

37. The method of claim 33, wherein the silicon germanium component has a thermal expansion coefficient within ±25% of the thermal expansion coefficient of the gallium nitride material layer.

38. A method of forming a semiconductor structure comprising:
forming a silicon germanium layer on a gallium nitride component.
